(19) United States
(12) Patent Application Publication
(10) Pub. No.: US 2010/0283051 A1
(43) Pub. Date: Nov. 11, 2010

(54) MONITOR CELL AND MONITOR CELL PLACEMENT METHOD

(75) Inventor: Cedric Mayor, Overasselt (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/811,989

(22) PCT Filed: Dec. 29, 2008
(86) PCT No.: PCT/IB08/55563

§ 371 Date: Jul. 7, 2010

(30) Foreign Application Priority Data
Jan. 11, 2008 (EP) 08290025.9
Dec. 29, 2008 (IB) PCT/IB2008/055563

(51) Int. Cl. H01L 29/00; G06F 17/50

(52) U.S. Cl. 257/48; 716/110; 716/101; 257/E21.521

(57) ABSTRACT

The present invention relates to a monitor cell (200) for monitoring local variations in a process parameter of an integrated circuit. The monitor cell (200) comprises a first delay path (220) located in a first area (100, 110, 120) of the integrated circuit and a second delay path (230) located in a second area (100, 110, 120) of the integrated circuit. The first delay path (220) is faster than the second delay path (230) when the difference in the respective process parameter values of the first area and the second area is smaller than a predefined threshold. In contrast, the second delay path (230) is faster than the first delay path (220) when said difference is larger than the predefined threshold. The monitor cell further comprises an input (210) arranged to provide the first delay path (220) and the second delay path (230) with a test signal (260) and a signal detector (240) for detecting the order in which the delay paths (210; 220) output the test signal (260). Such a monitor cell is capable of detecting intra-IC process variations. The present invention further relates to a method for inserting such a monitor cell in an IC design. According to the method, the monitor cell is inserted into the design by replacing a dummy cell with the monitor cell.

### FIELD OF THE INVENTION

The present invention relates to a monitor cell for monitoring local variations in a process parameter of an integrated circuit (IC).

The present invention further relates to a method of integrating a monitor cell into an integrated circuit (IC) layout.

### BACKGROUND OF THE INVENTION

When manufacturing semiconductor devices such as ICs, it is important that the devices are tested to ensure that a fault-free device is being produced. This is for instance of great importance in application domains where the correct functioning of the semiconductor device is directly correlated to the well-being or safety of a user, e.g. semiconductor devices used in medical or automotive application domains. The semiconductor device is typically tested several times during the various stages of the manufacturing process. For instance, each device may be tested while still forming part of a wafer to avoid faulty devices being further processed, e.g. packaged. Wafer tests can be useful insights into manufacturing process variations. These insights can be used to improve the manufacturing process to reduce the number of rejected devices.

It is known to test each die during a wafer test. To this end, the wafer may comprise a plurality of test monitors in its scribe lines to route test signals to and from individual dies. The difference in test results between dies in different areas of the wafer can be used to identify variations in the wafer manufacturing process. The advantage of such an inter-die test approach is two-fold. The inclusion of the monitors in the scribe lines avoids the need to physically contact the dies during the testing process, thus reducing the risk of damaging the die during testing, and obviates the need to sacrifice functional area on the die in case of a monitor being included in the IC design.

Due to the downscaling of feature sizes in semiconductor technology, the aforementioned inter-die test approach does no longer provide sufficiently detailed insights in process variations. This is because the downscaling of the feature sizes has reduced the footprint of such variations to within a single die. This is demonstrated in FIG. 1, where the variations in operating speed of a CMOS 090 die are depicted. Region 100 has a nominal device speed, whereas regions 110 have an increased device speed and regions 120 have a decreased device speed.

Consequently, in modern process technologies, e.g. technologies having submicron feature sizes, the granularity of the test approach has to be reduced to the intra-die level. In other words, several areas of a single die have to be tested and their test results compared to ensure that process variations inside the die do not exceed acceptable levels, since such variations may cause excessive local variations in for instance operating speed of the IC to be produced from the die.

US patent application No. 2006/0195737 A1 discloses an on-chip arrangement for determining operating characteristics of an IC having a scan chain. The IC comprises a control portion for placing the latches of the scan chain in an active mode and for providing a timing transition signal to the scan chain. The control portion further comprises a counter for counting the number of clock cycles it takes the timing transition signal to flush through the scan chain. This flush time provides an indication of the value of an operating parameter of the IC, such as its processing speed. Since the operating speed of an IC is directly related to variations in its process parameters, this method provides an indication of a global average value of such a process parameter.

UK patent application No. 2 327 127 A discloses an on-chip arrangement for verifying the timing of an IC. To this end, the IC is provided with a register circuit that feeds a transition signal to two inverter chain based delay paths that model different load conditions that a macro of the IC may encounter. The delay paths, which introduce a similar delay and are typically spread over a large area of the chip to capture variations of on-chip layout phenomenon, are fed back to a multiplexer of the register circuit, where one of the paths is selected for subsequent evaluation of the timing behavior of the selected path. The path is typically subjected with a plurality of transition signals with increasing frequency to determine at what frequency the register will fail to capture the delayed transition signal.

The aforementioned prior art arrangements typically target the capture of a chip-averaged variations in process parameters. However, such arrangements fail to provide an insight into the local variations in such process parameters, which prohibits an in-depth understanding of underlying causes for such variations.

### SUMMARY OF THE INVENTION

The present invention seeks to provide a monitor cell that allows for detecting intra-die process variations.

The present invention further seeks to provide a method of integrating such a monitor cell in an integrated circuit design.

According to a first aspect of the present invention, there is provided a monitor cell for monitoring local variations in a process parameter of an integrated circuit, said monitor cell comprising a first delay path located in a first area of the integrated circuit; a second delay path located in a second area of the integrated circuit, wherein the first delay path is faster than the second delay path when the difference in the respective process parameter values of the first area and the second area is smaller than a predefined threshold, and the second delay path is faster than the first delay path when said difference is larger than the predefined threshold; an input arranged to provide the first delay path and the second delay path with a test signal; and a signal detector for detecting the order in which the delay paths output the test signal.

Such a monitor cell is capable of detecting local variations in process parameters of a die or integrated circuit. In particular, the threshold may be defined in such a manner that too large variations, indicating a gradient in the process parameter spread in excess of acceptable levels, cause a change in the order in which the delay paths output the test signal to the signal detector. The signal detector may be implemented as a comparator using sequential and/or combinatorial circuitry.

In other words, the present invention is based on introducing a difference in a design parameter of the respective semiconductor devices in the first delay path and the second delay path such that the first delay path and the second delay path exhibit a difference in delay that is in the same order of magnitude as delay differences occurring between different process corners of a die or an IC.

In an embodiment of the present invention, the first delay path and the second delay path comprise an equal number of logic gates, a design parameter of said logic gates having a first value in the first delay path and a different value in the second delay path. In this embodiment, the delay difference between the delay paths is solely introduced by a variation in a design parameter such as channel length. The first delay path and the second delay path may comprise inverter chains having an equal number of inverters, the inverters of the second delay path having a slower signal response time than the inverters of the first delay path when said difference is below the predefined threshold. The first delay path will outrace the second delay path unless the first delay path is located in a process corner of the die that is substantially slower than the process corner of the second delay path. In the latter scenario, the difference in the process parameters will over-compensate the intrinsic difference in responsiveness between the first and second delay chain thereby causing the second delay path to outrace the first delay path.

In an alternative embodiment, the first delay path and the second delay path comprise a different number of logic gates. In this embodiment, the delay difference may be introduced by a difference in the number of elements in the delay chain. Preferably, a design parameter of said logic gates has a first value in the first delay path and a different value in the second delay path, such that a difference in the delay between the first delay path and the second delay path introduced by the difference in design parameter reduces the difference in the delay introduced by the difference in number of gates. The inclusion of the variation in the design parameter gives better control over designing the delay and monitoring process variations in the device under test.

The first delay path and the second delay path may comprise inverter chains of different lengths to ensure that the shorter length path outraces the longer length chain when the delay paths are located in comparable process corners. In case the inverter chain of the second delay path comprises more inverters than the inverter chain of the first delay path, the inverters of the second delay path may have a faster signal response time than the inverters of the first delay path to further tune the sensitivity to a difference in measured process parameter.

An integrated circuit comprising such a monitor cell may comprise a test signal input for providing the test signal to the monitor cell and a test result output for receiving a detection signal from the signal detector to facilitate off-chip test signal generation and detection. This is for instance advantageous when the IC is a packaged die, in which case the test is no longer performed at the wafer level.

Preferably, at least one of the test data input and the test result output are coupled to the monitor cell via a scan chain such as an IEEE 1149.1 (boundary scan test) compliant scan chain. This is particularly beneficial if the IC comprises a plurality of monitor cells, which each may be coupled to different scan cells in the scan chain arrangements to allow individual access.

According to a further aspect of the present invention, there is provided a method of integrating a monitor cell into an integrated circuit layout, comprising: providing a monitor cell according to the present invention; placing a plurality of active cells in a layer of the layout such that said layer has an initial cell density after said placing; increasing the cell density of the layer by placing dummy cells in vacant layer areas; and replacing at least one dummy cell with the monitor cell. Consequently, the monitor cell of the present invention may be integrated in the IC without increasing the active cell density during the routing and placement steps of the active cells in the IC design phase. Such dummy cells may include filler cells, decoupling cells and the like.

The introduction of dummy cells in an IC design is well-known in the art. For instance, U.S. Pat. No. 5,923,947, U.S. Pat. No. 5,854,125 and PCT patent application No. WO 01/43194 A1 disclose various methods for inserting dummy cells into e.g. a gate layer of an IC design to ensure that the pattern density is substantially constant over the semiconductor substrate such that subsequent etching and polishing steps do not cause variations in critical dimensions of devices on the semiconductor substrate. It is to be understood that the method of the present invention may be used with any suitable dummy cell insertion method such as but not limited to the methods disclosed in the aforementioned prior art documents. In fact, the method of the present invention may be used to insert any suitable monitor cell into an IC design, i.e. the method of the present invention is not limited to the insertion of monitor cells according to the present invention.

The method of the present invention may be implemented by means of a computer program product for producing an integrated circuit layout, the computer program product comprising instructions that implement said method when executed on a computer. The computer program product may be an IC design tool, and may be stored on any suitable data carrier such as a CD-ROM, DVD, memory stick, a hard-disk, which may be accessible via a network such as the internet, or any other suitable storage medium.

### BRIEF DESCRIPTION OF THE DRAWINGS

Embodiments of the invention are described in more detail and by way of non-limiting examples with reference to the accompanying drawings, wherein:

FIG. 1 schematically depicts a process parameter spread map of a CMOS 090 die;

FIG. 2 schematically depicts the general principle of the monitor cell of the present invention;

FIG. 3 schematically depicts an embodiment of a monitor cell of the present invention;

FIG. 4 schematically depicts an alternative embodiment of a monitor cell of the present invention; and

FIG. 5 schematically depicts a flow chart of an embodiment of the method of the present invention.

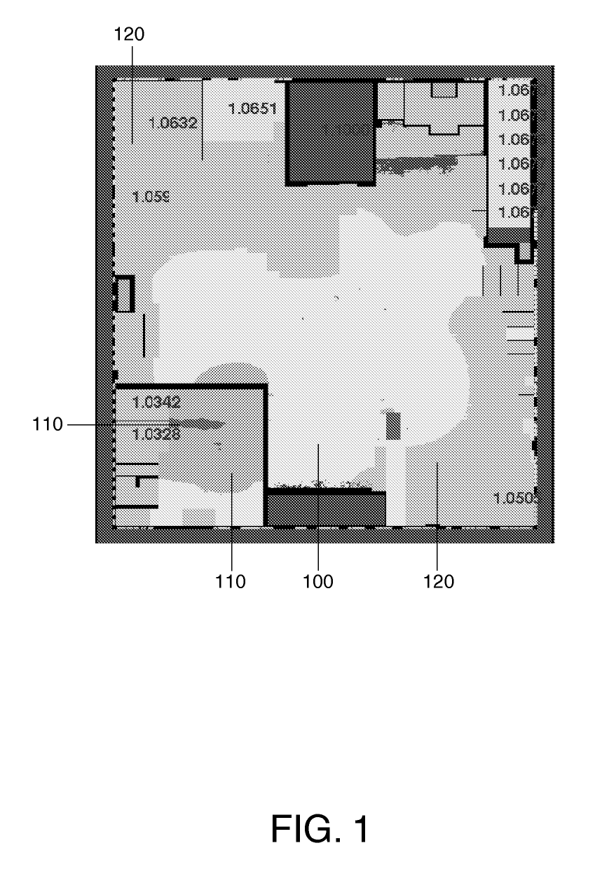

### DETAILED DESCRIPTION OF EMBODIMENTS

It should be understood that the Figures are merely schematic and are not drawn to scale. It should also be understood that the same reference numerals are used throughout the Figures to indicate the same or similar parts.

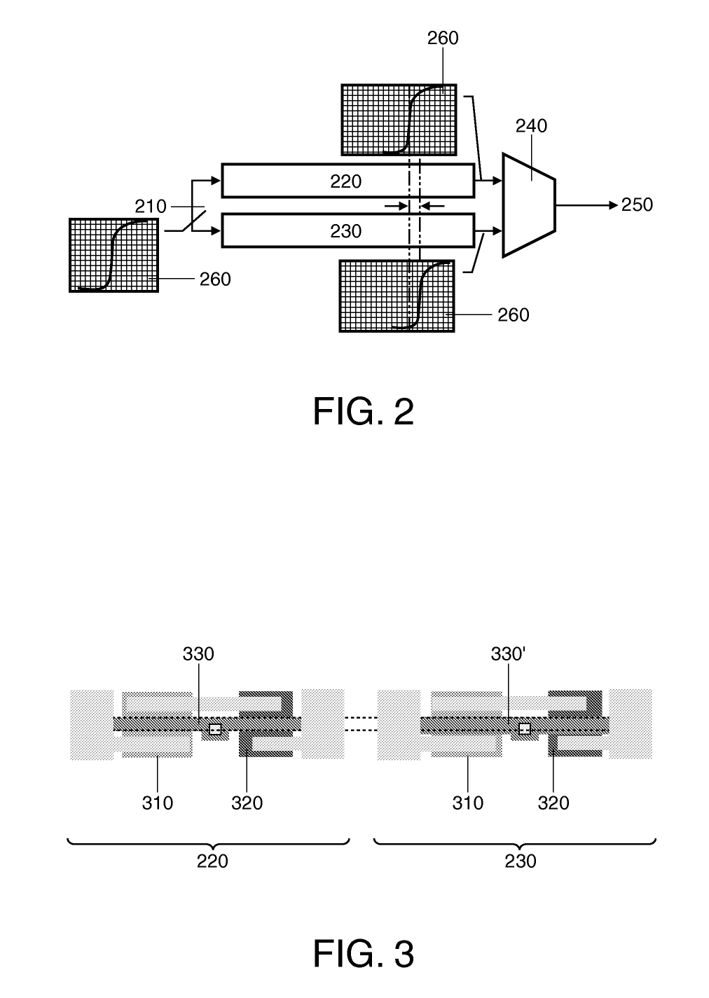

FIG. 2 depicts the general concept of the monitor cell 200. The monitor cell 200 is designed to monitor variations in process parameters between local areas of an integrated circuit. In the context of the present invention, the phrase ‘IC’ is intended to include an unpackaged die, which may still be a part of a wafer comprising a plurality of such dies. The monitor cell 200 comprises a signal fork having two unbalanced branches, i.e. a first delay path 220 and a second delay path 230. The first delay path 220 is typically located in a first area of the IC, whereas the second delay path 230 is typically located in a second area of the IC. The first and second IC areas may be neighboring areas or areas that are further separated from each other. The first delay path 220 and the second delay path 230 comprise similar device structures, e.g. transistors, which may be grouped into logic gates.

The signal fork is coupled between an input 210 and a signal detector 240, which may be implemented as a sequential logic-based or a combinatorial-logic based comparator or arbiter. Other suitable implementations may also be chosen. The signal detector 240 has an output 250 for providing a signal indicative of the order in which the test signal arrived at the signal detector 240 from the first delay path 220 and the second delay path 230. The output 250 may be coupled to an output pin (not shown) of the IC on which the monitor cell 200 is placed. The output 250 may be coupled to the IC output pin via a shift register (no shown) such as a boundary scan compliant scan chain under control of a test access port controller (not shown). In this case, the IC output pin may be the boundary scan test data output (TDO) pin.

The first delay path 220 and the second delay path 230 are designed to have different delay characteristics when the first area and the second area are sufficiently similar in terms of a parameter that is sensitive to process variations, e.g. process speed.

To this end, an intrinsic delay difference is introduced between the first delay path 220 and the second delay path 230 by variation of a design parameter, e.g. a variation in device dimension and/or device characteristics, e.g. dopant concentrations, number of contacts and so on. The overall delay experienced by a test signal 260 provided to the signal trace fork can be expressed as follows:

Δt₍₂₂₀₎=Δtᵢ(220)+Δt_{process}(220)

Δt₍₂₃₀₎=Δtᵢ(230)+Δt_{process}(230)

wherein Δt is the overall delay experienced by the test signal 260 in a delay path. Δt comprises a delay component Δt, which is an ‘intrinsic’ delay introduced into the delay path by means of the design parameter choice, and a delay component Δt_{process}, which is process parameter dependent. The process parameter delay component is defined with respect to a delay introduced at a nominal process parameter value, i.e. Δtₙₒₘᵢₙₐₗ=0, which means that a delay experienced in a slow process corner will have a positive value and a delay experienced in a fast process corner will have a negative value. For a ‘good’ IC, i.e. an IC having process parameter variations within acceptable spread boundaries, the following condition holds:

(Δtᵢ(230)−Δtᵢ(220))>(Δt_{process}(220)−Δt_{process}(230))<=>

Δt₍₂₃₀₎>Δt₍₂₂₀₎

In contrast, when the variation in process parameter dependent delay component exceeds the predefined threshold, i.e. the intrinsic delay difference introduced between the first delay path 220 and the second delay path 230, the following condition holds:

(Δtᵢ(230)−Δtᵢ(220))<(Δt_{process}(220)−Δt_{process}(230))<=>

Δt₍₂₃₀₎<Δt₍₂₂₀₎

In other words, the first delay path 220 and the second delay path 230 have a designed intrinsic delay difference such that when the circuit under test performs within design specifications, the propagation of a test signal 260, e.g. a signal transition, one delay path, i.e. first delay path 220 in the above conditions, will always outrace the other delay path, i.e. second delay path 230 in the above conditions, as indicated in FIG. 2. It will be appreciated that the intended race order of these delay paths may be swapped without departing from the teachings of the present invention.

In quantifying the process parameter variation between two IC areas, two monitor cells, each having a delay path in one of the areas may be used. The first monitor cell may be used to determine if Δt_{process}(220)−Δt_{process}(230) exceeds a positive threshold value, whereas the second monitor cell may be used to determine if Δt_{process}(220)−Δt_{process}(230) exceeds a negative threshold value. In other words, the first monitor cell will determine if the first area is much faster than the second area, whereas the first monitor cell will determine if the first area is much slower than the second area, for instance because of large differences in the geometry of transistors in the different IC areas or because of differences in the intrinsic device speed in those areas. This way, both boundaries of the allowable process parameter spread may be verified. The two separate monitor cells may be combined into a single monitor cell having four delay paths.

An alternative embodiment of the combined monitor cell has a signal fork comprising only three delay paths; one reference path in one area of the IC and two paths, i.e. a fast path and a slow path with respect to the reference path in another area of the IC. A first comparator compares the signal arrival order between the fast path and the reference path, and a second comparator compares the signal arrival order between the slow path and the reference path.

The intrinsic difference in the delay between the first delay path 220 and the second delay path 230, i.e. (Δtᵢ(220)-Δtᵢ(230)), may be realized by a change in a device rule variation in the devices forming one of the delay paths, and/or may be invoked by different numbers of devices in each delay path.

An example of an introduced intrinsic difference in delay between the first delay path 220 and the second delay path 230 by variation of a design parameter is shown in FIG. 3. In this embodiment, the process parameter variation under investigation is the variation in the geometry of devices located in different areas of an IC. In this embodiment, the first delay path 220 and the second delay path 230 both comprise a chain of logic gates such as an inverter chain, each comprising the same number of logic gates, e.g. inverters. The inverters may be implemented in any suitable way. To introduce an additional delay in the test signal propagation through the second delay path 230, the design rule, i.e. the design specification, of the inverter transistors of the inverter chain of the second delay path 230 is changed compared to the design rule of the transistors of the first delay path 220.

The transistors in the first delay path 220 and the second delay path 230 have identical P regions 310 and N regions 320 in terms of design specification. However, the length of the gate channel 310′ of the transistors in the second delay path 230 is extended with respect of the length of the gate channel 310 of the transistors in the first delay path 220, thus introducing an additional delay in the response time of the transistors in the second delay path 230.

Hence, the first delay path 220 will outrace the second delay path 230 unless the second delay path 230 is located in an area of the IC that has a that is substantially faster than the area of the IC harboring the first delay path 220, i.e. in which the deviation from the intended process geometry overcompensate the intrinsic geometric design variation. In such a scenario, the variations in the process parameters may cause the intrinsically slow second delay path 230 to outrace the intrinsically fast first delay path 220.

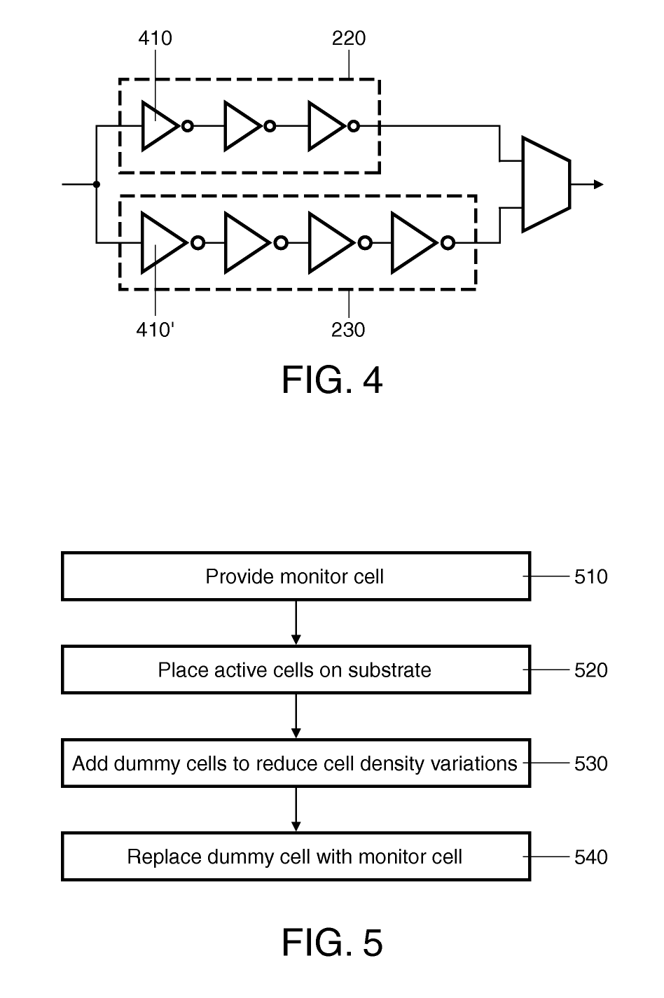

Another example of an introduced intrinsic difference in delay between the first delay path 220 and the second delay path 230 is shown in FIG. 4. In this embodiment, the process parameter variation under investigation is the variation in intrinsic device speed between different areas of an IC. To quantify such variations, the first delay path 220 comprises a first inverter chain and the second delay path 230 comprises a second inverter chain. The first inverter chain comprises M inverters 410 and the second inverter chain comprises N inverters 410′. M and N are integer numbers with M<N. This should give the first delay path 220 a much smaller delay than the second delay path 230. However, the difference in delay between the first delay path 220 and the second delay path 230 is reduced by the introduction of a variation in a design parameter of the inverter transistors. In FIG. 4, the transistors in inverters 410′ are larger than the transistors in inverters 410. In other words, the inverters 410′ invert a received signal more quickly than the inverters 410.

By using different numbers of inverters with different dimensions in both delay paths, the effective intrinsic delay difference (Δtᵢ(230)-Δtᵢ(220)) can be accurately tuned to detect predefined differences in intrinsic device speed between the areas of the IC under investigation. If the second delay path 230 is located in much faster process corner of the IC than the first delay path 220, the second delay path 230 will now outrace the first delay path 220 despite the fact that the second delay path 230 has more inverters than the first delay path 220.

In this particular example, the size of the transistor in the two inverter chains is varied by adjusting the width/length ratio of the transistor channel in order to affect the saturation current I_{DSAT} of the modified transistors. However, it will be appreciated that other design rule variations such as the number of contacts, implant concentrations and/or profiles and so on to influence the delay characteristics of the devices in a delay path may also be used.

Another aspect of the present invention relates to a method for integrating a monitor cell of the present invention into an IC design. As indicated in the background section of this application, a drawback of adding monitor cells to an IC design is that it adds to the silicon real estate of the IC. This introduces cost, and increases the complexity of the IC design in terms of placement of the active cells on the semiconductor substrate and the routing between the cells. It has been realized that since the size of the monitor cells of the present invention is comparable to the size of most dummy cells used to provide an IC design having a homogeneous cell density, such a cell may be introduced after the dummy cells have been introduced in the IC design by simply removing a dummy cell in a region of interest and replacing the dummy cell with a monitor cell. This is schematically depicted in FIG. 5.

In a first step 510, a monitor cell such as a monitor cell of the present invention is provided. However, any monitor cell having comparable dimensions such that they can replace a dummy cell may be provided.

In a next step 520, of the IC design process, the active cells are placed on the semiconductor substrate area in accordance with a design specification. Such a step is typically followed by a step 530 in which dummy cells are placed in areas of the semiconductor substrate devoid of active cells to ensure that the distance between neighboring cell boundaries does not exceed a predefined threshold. Such a threshold is typically indicative of the minimum distance at which device variations may occur because of the unwanted occurrence of non-planar etching profiles in subsequent etching steps.

In accordance with the present invention, an additional step 540 is executed in which a dummy cell placed in an area of interest is removed and replaced with a monitor cell. Hence, a monitor cell is introduced in the IC design without complicating the placement of active cells. The method of the present invention is preferably implemented by means of a computer program such as an IC CAD tool. The modification of existing CAD tools for adding dummy cells to an IC design in order to implement the method of the present invention will be apparent to the skilled person, and will therefore not be explained in any detail for the sake of brevity.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A monitor cell for monitoring local variations in a process parameter of an integrated circuit, said monitor cell comprising:
a first delay path located in a first area of the integrated circuit;
a second delay path located in a second area of the integrated circuit, wherein the first delay path is faster than the second delay path when the difference in the respective process parameter values of the first area and the second area is smaller than a predefined threshold, and the second delay path is faster than the first delay path when said difference is larger than the predefined threshold;
an input arranged to provide the first delay path and the second delay path with a test signal; and
a signal detector for detecting the order in which the delay paths; output the test signal.

2. A monitor cell as claimed in claim 1, wherein the first wherein the first delay path and the second delay path each comprise a plurality of semiconductor elements, a design parameter of said semiconductor elements having a first value in the first delay path and a different value in the second delay path.

3. A monitor cell as claimed in claim 2, wherein the first delay path and the second delay path comprise an equal number of logic gates.

4. A monitor cell as claimed in claim 3, wherein the first delay path and the second delay path each comprise a chain of inverters.

5. A monitor cell as claimed in claim 4, wherein each of the inverters in the inverter chain of the first delay path comprise transistors having respective gates with a smaller gate length than the gate length of the respective gates of the inverter transistors in the inverter chain of the second delay path.

6. A monitor cell as claimed in claim 1, wherein the first delay path and the second delay path comprise a different number of logic gates.

7. A monitor cell as claimed in claim 6, wherein a design parameter of said logic gates has a first value in the first delay path and a different value in the second delay path, such that a difference in the delay between the first delay path and the second delay path introduced by the difference in design parameter reduces the difference in the delay introduced by the difference in number of gates.

8. A monitor cell as claimed in claim 7, wherein the first delay path and the second delay path comprise inverter chains of different lengths.

9. A monitor cell as claimed in claim 1, wherein the signal detector comprises a comparator.

10. An integrated circuit comprising:
a monitor cell as claimed in claim 14;
a test signal input for providing the test signal to the monitor cell input; and
a test result output for receiving a detection signal from the signal detector.

11. An integrated circuit as claimed in claim 10, wherein at least one of the test data input and the test result output are coupled to the monitor cell via a scan chain.

12. A method of integrating a monitor cell into an integrated circuit layout, comprising:
providing a monitor cell as claimed in claim 14,
placing a plurality of active cells in a layer of the layout such that said layer has an initial cell density after said placing;
increasing the cell density of the layer by placing dummy cells in vacant layer areas; and
replacing at least one dummy cell with the monitor cell.

13. A computer program product for producing an integrated circuit layout, the computer program product comprising instructions that, when executed on a computer, implement the steps of the method of claim 12.

14. A monitor cell as claimed in claim 1, comprising
a further delay path in the first area, the further delay path being slow with respect to the second path, the input being arranged to provide the further delay path with the test signal, and
a further signal detector for detecting the order in which the further delay path and the second delay path output the test signal.
